(19) United States
(12) Patent Application Publication
(10) Pub. No.: US 2014/0291753 A1
(43) Pub. Date: Oct. 2, 2014

(54) TRENCH MOSFET STRUCTURE HAVING SELF-ALIGNED FEATURES FOR MASK SAVING AND ON-RESISTANCE REDUCTION

(71) Applicant: FORCE MOS TECHNOLOGY CO., LTD., New Taipei City (TW)

(72) Inventor: FU-YUAN HSIEH, New Taipei City (TW)

(73) Assignee: Force Mos Technology Co., Ltd., New Taipei City (TW)

(21) Appl. No.: 13/851,185

(22) Filed: Mar. 27, 2013

(51) Int. Cl. H01L 29/66; H01L 29/78

(52) U.S. Cl. CPC H01L 29/66666; H01L 29/7827
USPC 257/330; 438/270

(57) ABSTRACT

A trench MOSFET structure having self-aligned features for mask saving and on-resistance reduction is disclosed, wherein the source region is formed by performing source Ion Implantation through contact opening of a contact interlayer, and further source diffusion. A dielectric sidewall spacer is formed on sidewalls of the contact interlayer in the contact open areas to define trenched source-body contacts for on-resistance reduction and avalanche capability improvement.

### FIELD OF THE INVENTION

This invention relates generally to the cell structure, layout and fabrication process of power semiconductor devices. More particularly, this invention relates to a novel and improved cell structure, layout and improved process for fabricating trench metal-oxide-semiconductor-field-effect-transistor (MOSFET) structure having self-aligned features for mask saving and on-resistance reduction.

### BACKGROUND OF THE INVENTION

In U.S. Pats. No. 6,888,196 and 7,816,720, a trench MOSFET 100 was disclosed with n+ source regions 101 disposed in an upper portion of P body region 102 flanking trenched gate 103 in an active area, as shown in FIG. 1, wherein the width of contact opening is as same as the width of trenched source-body contact 104. The n+ source regions 101 have a same doping concentration at a same distance from a top surface of N epitaxial layer 105, and the n+ source regions 101 have a same junction depth from the top surface of the N epitaxial layer 105.

The same prior art U.S. Pat. No. 7,816,720 shows another trench MOSFET 200 in FIG. 2A for saving source mask by using contact mask as self-aligned source mask as disclosed in FIG. 2B and 2C. In FIG. 2B, the n+ source regions 201 are formed by source dopant ion implantation through a contact opening having a width of CO, as illustrated in FIG. 2B and source diffusion followed. In FIG. 2C, a dry silicon etch is carried out to define trenched source-body contact having a width of SBCO, as illustrated in FIG. 2C, wherein the width of the contact opening is as same as the width of the trenched source-body contact. Then, a p+ body contact area 202 is formed around bottom of the trenched source-body contact by contact dopant ion implantation. Referring back to FIG. 2A, the n+ source regions 201 have a doping concentration along sidewalls of trenched source-body contact 203 higher than along adjacent channel region near trenched gates 204 in an active area at a same distance from a top surface of N epitaxial layer 205, and the n+ source regions 201 have a junction depth along the sidewalls of the trenched source-body contact 203 in the active area greater than along the adjacent channel region from the top surface of the N epitaxial layer 205, and the n+ source regions 201 have a doping profile of Gaussian-distribution along the top surface of the N epitaxial layer 205 from the sidewalls of the trenched source-body contact 203 in the active area to the adjacent channel region. Since the n+ source regions 201 in FIG. 2A has a Gaussian distribution from the trenched source-body contact 203 toward the adjacent channel region, a parasitic source resistance Rn+ of the source regions 201 from the adjacent channel region to the trenched source-body contact 203 may be higher than the conventional device as shown in FIG. 1, causing higher Rds issue. And this problem becomes pronounced specially for P channel devices because source dopant boron has solid solubility about 5 and 7 times less than phosphorus and arsenic, respectively, resulting in high Rds issue. The problem may be simply resolved by enlarging the contact opening to allow more dopant to implant into the source regions and to drive in close to the adjacent channel region, however, Vth may be increased if space between the adjacent channel region and the body contact area Rcp+ (defined by Scp+) is too narrow, also causing high Rds at low Vgs. Moreover, the enlarged contact opening may easily results in gate to source shortage, causing low yield issue because of contact CD variation and poor misalignment tolerance.

Therefore, there is still a need in the art of the semiconductor device design and fabrication, particularly for trench MOSFET design and fabrication, to provide a novel cell structure, device configuration and fabrication process that would resolve these difficulties and design limitations. Specifically, it is desirable to save source mask of a trench MOSFET, meanwhile, not causing high Rds issue.

### SUMMARY OF THE INVENTION

The present invention provides trench MOSFET having self-aligned features for mask saving and on-resistance reduction, and further provides a trench MOSFET layout with multiple trenched floating gates and at least one trenched channel stop gate in termination area to make it feasibly achieved after sawing.

According to one aspect, the invention features a trench MOSFET formed in an epitaxial layer of a first conductivity type and comprising a plurality of first trenched gates with each surrounded by a source region heavily doped with the first conductivity type in an active area encompassed in a body region of a second conductivity type above a drain region disposed on a bottom surface of a substrate of the first conductivity type, further comprising: a trenched source-body contact starting from a contact interlayer over the epitaxial layer, having upper sidewalls surrounded by a dielectric sidewall spacer close to the contact interlayer, further penetrating through the source region and extending into the body region, connecting the source region and the body region to a source metal onto the contact interlayer; wherein the source region has a lower doping concentration and a shallower source junction depth along a channel region than under the dielectric sidewall spacer at a same distance from a surface of the epitaxial layer.

Please refer to FIG. 3A, the present invention has enlarged contact open with a width CO′ and enlarged trenched source-body contact with a width SBCO′, wherein the CO′ is larger than SBCO′. In comparison with the prior art in FIG. 2C where the CO=SBCO, the dielectric sidewall spacer with a width Ssw disposed surrounding the upper sidewalls of the trenched source-body contact defines the trenched source-body contact region, and the CO′=SBCO′+2Ssw. Therefore, the advantage of the present invention is reducing Rn+ without increasing Vth, because Rcp+ is kept the same as the prior art.

According to another aspect, in some preferred embodiment, the first conductivity type is N type and the second conductivity type is P type. Alternatively, the first conductivity type is P type and the second conductivity type is N type.

According to another aspect, in some preferred embodiment, the contact interlayer over the epitaxial layer can be implemented by using a single layer, for example NSG (non-doped silicon Glass) such as silicon rich oxide (SRO), and etc. In some other preferred embodiment, the contact interlayer also can be implemented by being composed of NSG and BPSG (Boron Phosphorus Silicon Glass).

According to another aspect, the invention further comprises a termination area having multiple trenched floating gates surrounded by the body region and surrounding outer of the active area. More preferred, the invention further comprises at least one trenched channel stop gate formed in the termination area and around outside of the multiple trenched floating gates, wherein each the trenched channel stop gate is connected to at least one sawing trenched gate, wherein each the sawing trenched gate is extended across a scribe line.

The present invention also features a semiconductor power device layout comprising dual trench MOSFETs consisted of two trench MOSFETs connected together with multiple sawing trenched gates in such a way that a space between the two trench MOSFETs is as same as scribe line width, wherein each the sawing trenched gate is connected with trenched channel stop gate of the dual trench MOSFETs. Therefore, after sawing, the multiple sawing trenched gates will be sawed through so that the dual trench MOSFETs will be separated.

According to another aspect, the invention features a method for forming the trench MOSFET comprising: forming a plurality of trenched gates surrounded by body regions in an epitaxial layer; forming a contact opening in a contact interlayer over the epitaxial layer to expose a part top surface of the epitaxial layer, wherein the contact opening is located between every two adjacent of the trenched gates; implanting the epitaxial layer with source dopant through the contact opening; forming dielectric sidewall spacers on sidewalls of the contact opening and close to the contact interlayer and diffusing the source dopant to form source regions surrounding the trenched gates; and carrying out a dry silicon etch along the dielectric sidewall spacers formation to further etch the contact opening through the source region and extend into the body region.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a trench MOSFET in prior art.

FIGS. 2A to 2C are cross-sectional views of another trench MOSFET in prior art.

FIG. 3A is a cross-sectional view of a preferred embodiment according to the present invention.

FIGS. 3B to 3E are cross-sectional views showing the forming steps of sidewall spacer and source regions of the preferred embodiment according to the present invention.

FIG. 4 is a cross-sectional view of another preferred embodiment according to the present invention.

FIG. 5A is a cross-sectional view of another preferred embodiment according to the present invention.

FIG. 5B is a cross-sectional view of another preferred embodiment according to the present invention.

FIG. 6A is a cross-sectional view of another preferred embodiment according to the present invention.

FIG. 6B is a cross-sectional view of another preferred embodiment according to the present invention.

FIG. 7A is a cross-sectional view showing a preferred A-B-C cross section of FIG. 7B according to the present invention.

FIG. 7B shows a dual dies layout of a preferred embodiment according to the present invention.

FIG. 7C shows two dual dies layout of a preferred embodiment according to the present invention.

FIG. 7D shows multiple dual dies layout of a preferred embodiment according to the present invention.

FIGS. 8A to 8E are cross-sectional views for showing manufacturing steps of the trench MOSFET in FIG. 5A according to the present invention.

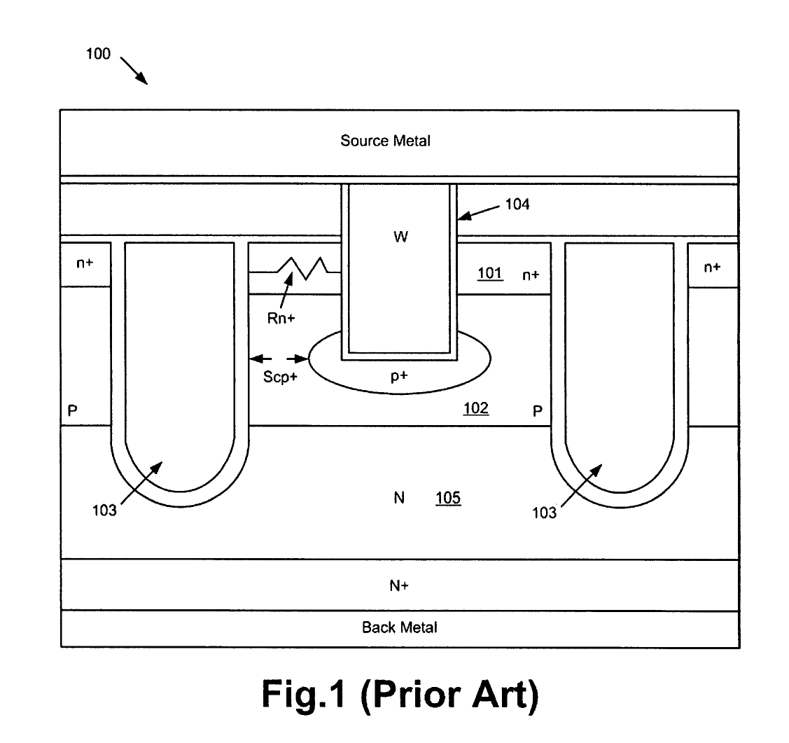

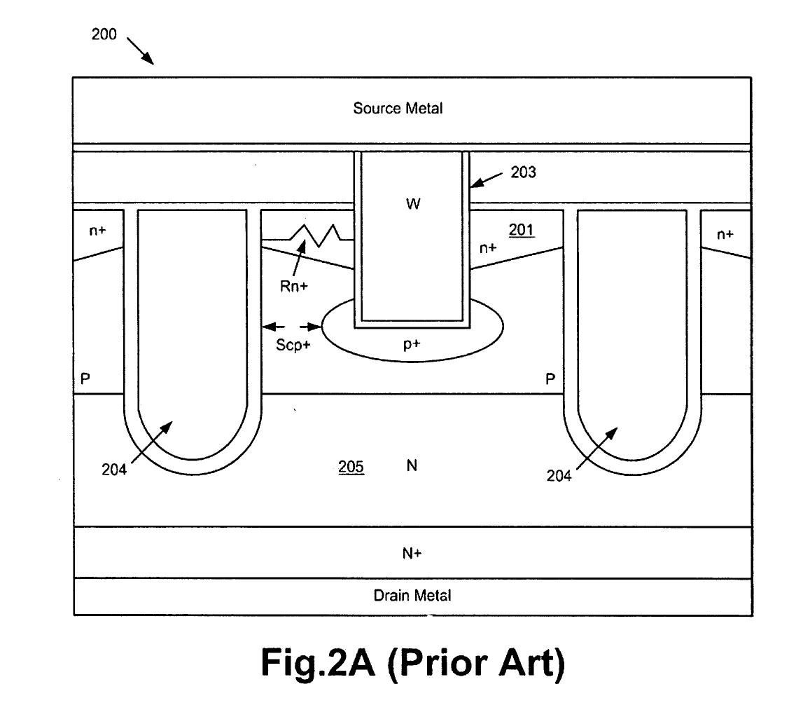

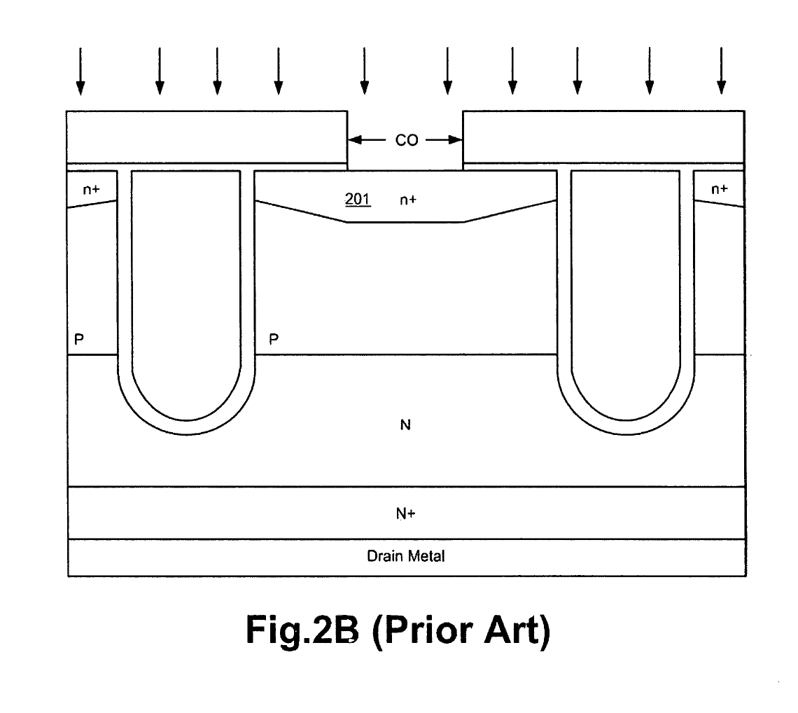

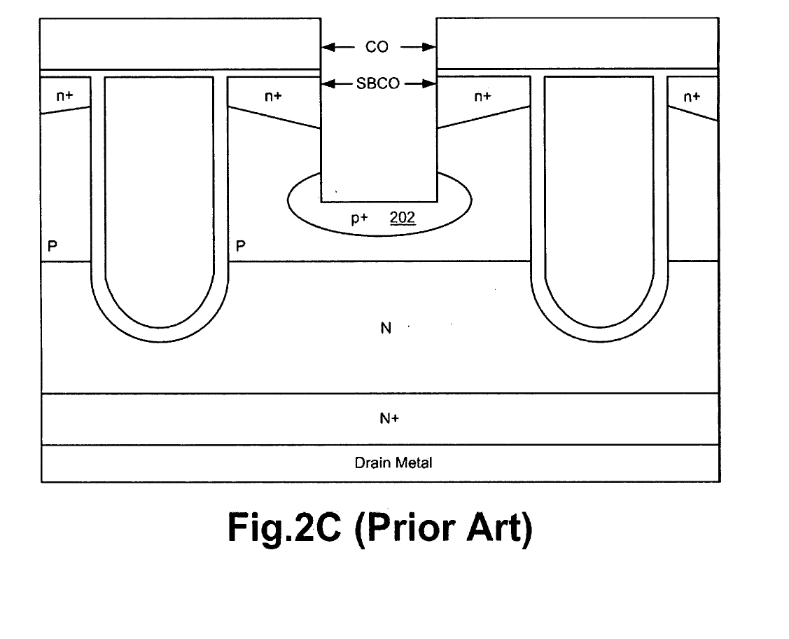

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

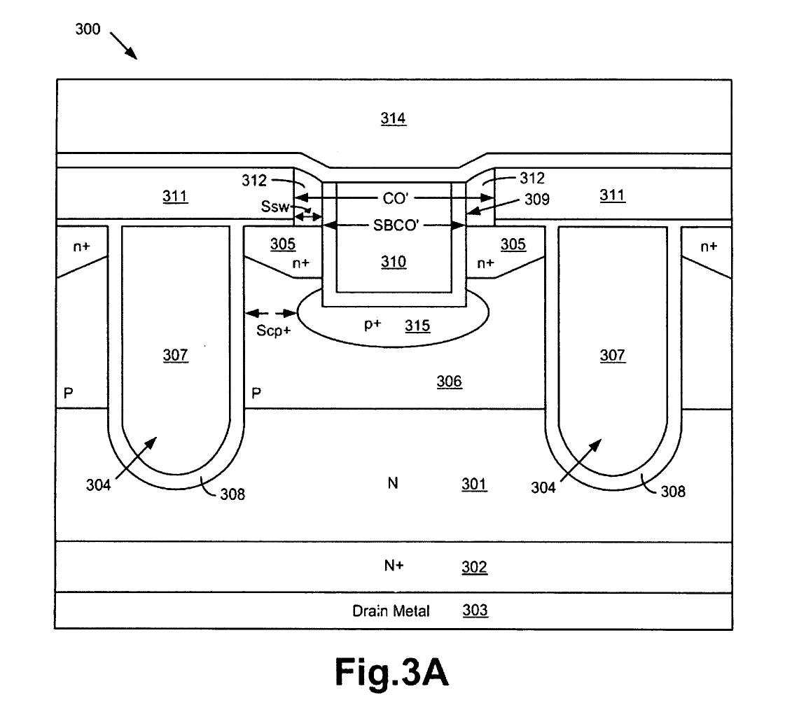

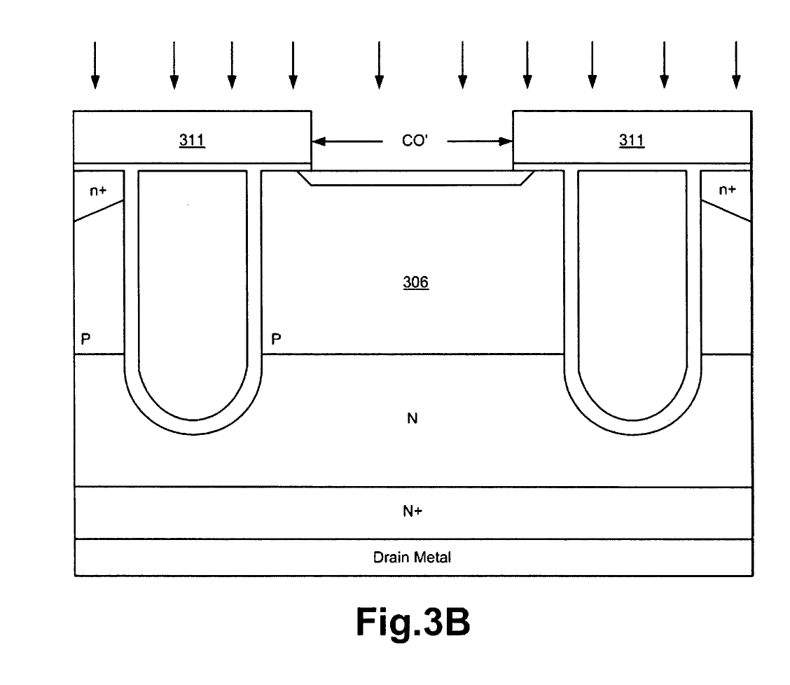

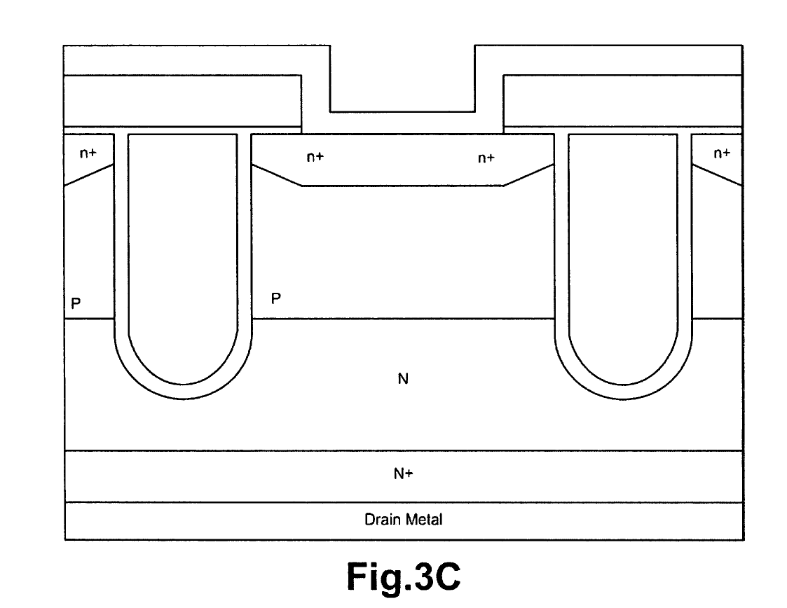

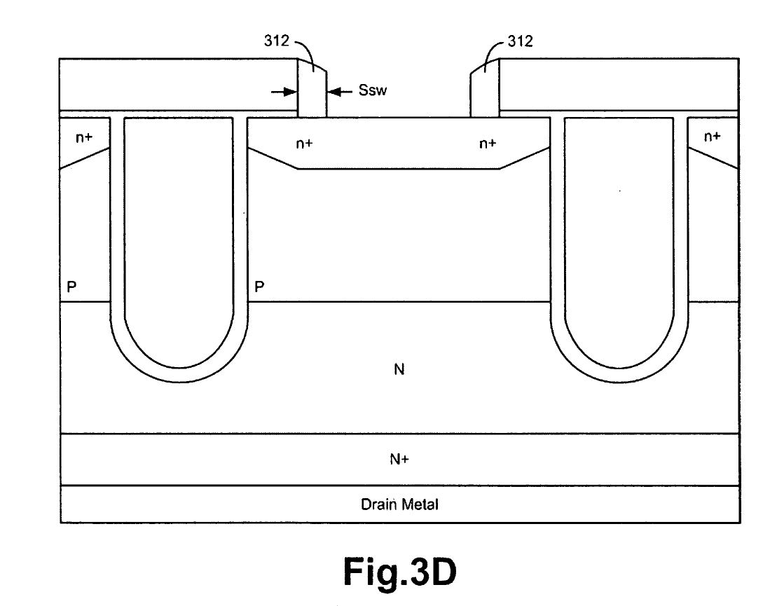

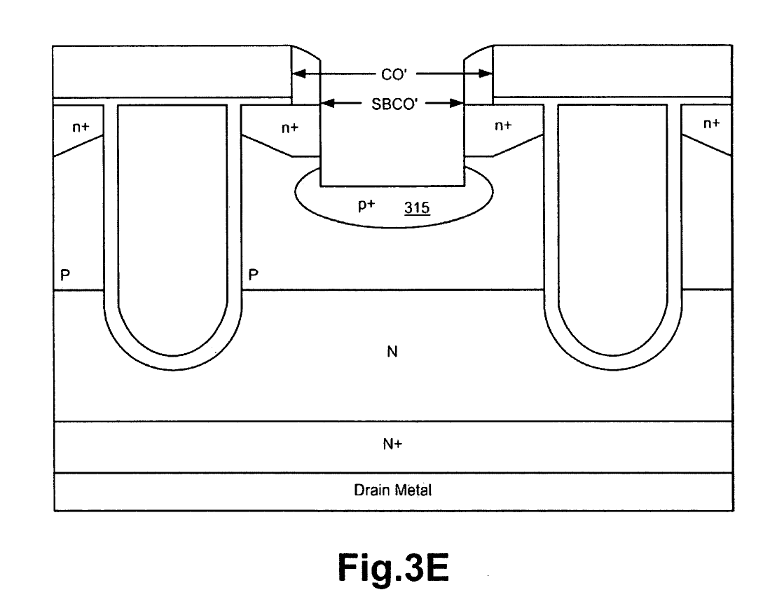

Please refer to FIG. 3A for a preferred embodiment of this invention wherein an N-channel trench MOSFET 300 is formed in an N epitaxial layer 301 onto an N+ substrate 302 with a metal layer on rear side as drain metal 303 (the conductivity type here is not to be taken in a limiting sense, which means it also can be implemented to be a P-channel trench MOSFET formed in a P epitaxial layer onto a P+ substrate). Inside the N epitaxial layer 301, a plurality of trenched gates 304 with each surrounded by an n+ source region 305 encompassed in a P body region 306 are formed in an active area. All the trenched gates 304 are formed by filling a doped poly-silicon layer 307 padded by a gate oxide layer 308 in a gate trench. The N-channel trench MOSFET 300 further comprises a trenched source-body contact 309 filled with a contact metal plug 310 penetrating a contact interlayer 311, the n+ source regions 305 and extending into the P body regions 306, wherein the contact metal plug 310 can be implemented by using a tungsten metal plug padded by a barrier layer of Ti/TiN or Co/TiN or Ta/TiN. What should be noticed is that, an upper sidewalls of the trenched source-body contact 309 penetrating though the contact interlayer 311 is surrounded by a dielectric sidewall spacer 312 which is sandwiched between the trenched source-body contact 309 and the contact interlayer 311, therefore CO′=SBCO′+2Ssw. Meanwhile, the n+ source region 305 has a lower doping concentration and a shallower source junction depth along a channel region than under the dielectric sidewall spacer 312 at a same distance from a top surface of the N epitaxial layer 301, and the doping profile of the n+ source region 305 along the surface of the N epitaxial layer 301 has a Gaussian-distribution from under the dielectric sidewall spacer 312 to an adjacent channel region. The N-channel trench MOSFET 300 further comprises a source metal 314 connected to the n+ source regions 305 and the P body regions 306 through the trenched source-body contact 309, wherein the source metal 314 is Al alloys or Cu alloys padded by a resistance-reduction layer Ti or Ti/TiN underneath. By using this structure, the resistance Rn+ of the n+ source regions 305 in the present invention is less than the prior art while Rcp+ is kept same to avoid high Vth. The dielectric sidewall spacer 312 can be implemented by using oxide, nitride or oxynitride. A p+ body contact area 315 is formed wrapping at least bottom of the trenched source-body contact 309 to further reduce contact resistance between the contact metal plug 310 and the P body regions 306.

FIGS. 3B to 3E are cross-sectional views showing the forming steps of the dielectric sidewall spacer 312 and the n+ source regions 305 of FIG. 3A according to the present invention. In FIG. 3B, a dry oxide etch is carried out to define a contact opening with a width of CO′ in the contact interlayer 311, and then source dopant is implanted into the P body region 306 through the contact opening. Afterwards, in FIG. 3C, a dielectric layer is deposited on top surface of the whole structure in FIG. 3B, followed by a source diffusion step. In FIG. 3D, a dry oxide etch is carried out to form the dielectric sidewall spacer 312 along each sidewall of the contact opening wherein each dielectric sidewall spacer 312 has a width of Ssw. In FIG. 3E, a dry silicon etch is carried out to further dig the contact opening having a width of SBCO′ into the P boy region 306. Then body contact dopant is implanted through the contact opening into the P body region 306 to form p+ body contact areas 315 around at least bottom of the trenched source-body contact. Therefore, CO′=SBCO′+2Ssw.

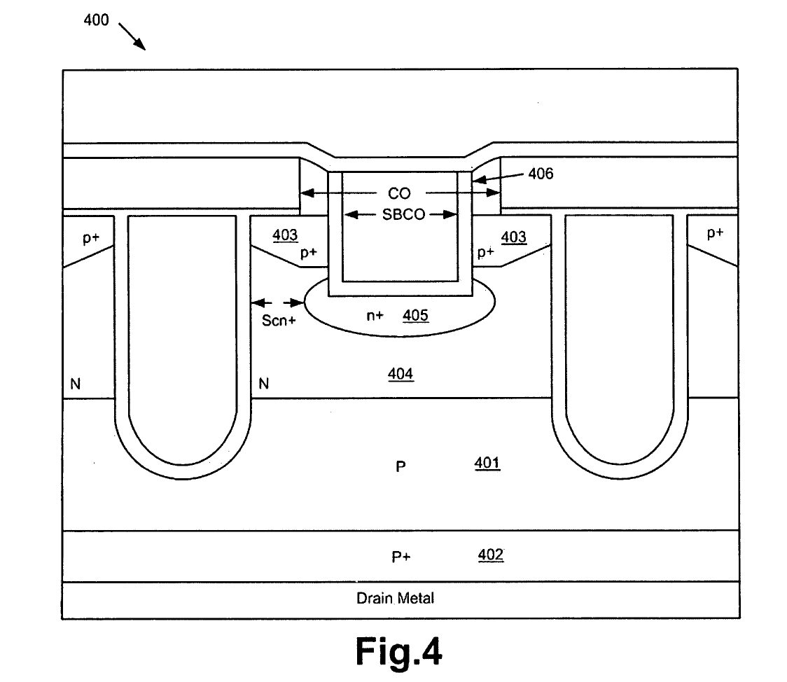

FIG. 4 shows another preferred embodiment of this invention wherein trench MOSFET 400 has a similar structure to the trench MOSFET 300 of FIG. 3A except the trench MOSFET 400 is P-channel trench MOSFET while the trench MOSFET 300 is N-channel MOSFET. The P-channel trench MOSFET 400 is formed in a P epitaxial layer 401 onto a P+ substrate 402, comprising p+ source regions 403 in an upper portion of N body regions 404 and n+ body contact areas 405 around bottoms of trenched source-body contacts 406.

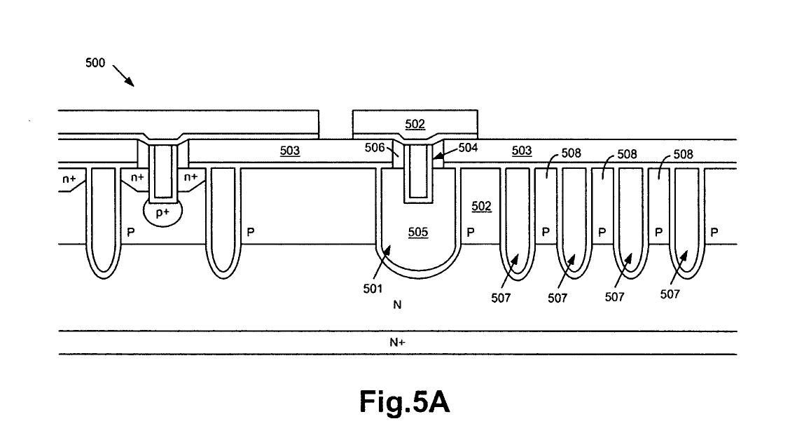

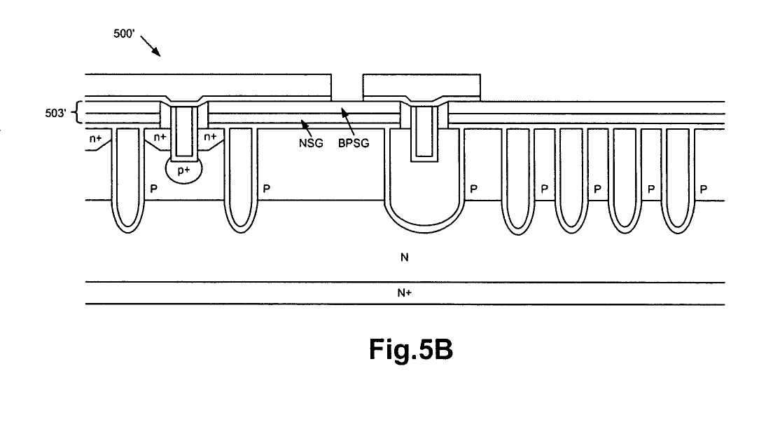

FIG. 5A shows another preferred embodiment of this invention wherein trench MOSFET 500 has a similar structure to the trench MOSFET 300 of FIG. 3A except the trench MOSFET 500 further comprises a trenched connection gate 501 adjacent to the active area and having a greater width than the trenched gates in the active area, which is connected to a gate metal layer 502 onto the contact interlayer 503 through a trenched gate contact 504 which is penetrating through the contact interlayer 503 and extending into the poly silicon layer 505 in the trenched connection gate 501, wherein an upper sidewalls of the trenched gate contact 504 is also surrounded by the dielectric sidewall spacer 506. Furthermore, the trench MOSFET 500 further comprises a termination area having multiple trenched floating gates 507 surrounded by the P body regions 508, wherein no source region is formed between two adjacent of the trenched floating gates 507 in the termination area. The contact interlayer 503 of the trench MOSFET 500 is non-doped silicate glass (NSG) such as silicon rich oxide (SRO).

FIG. 5B shows another preferred embodiment of this invention wherein trench MOSFET 500′ has a similar structure to the trench MOSFET 500 of FIG. 5A except the contact interlayer 503′ of the trench MOSFET 500′ is composed a layer of NSG and a layer of boron-phosphorus-silicate glass (BPSG).

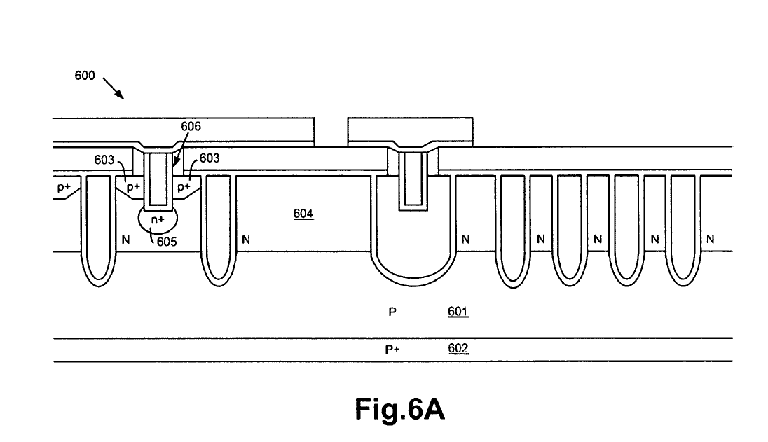

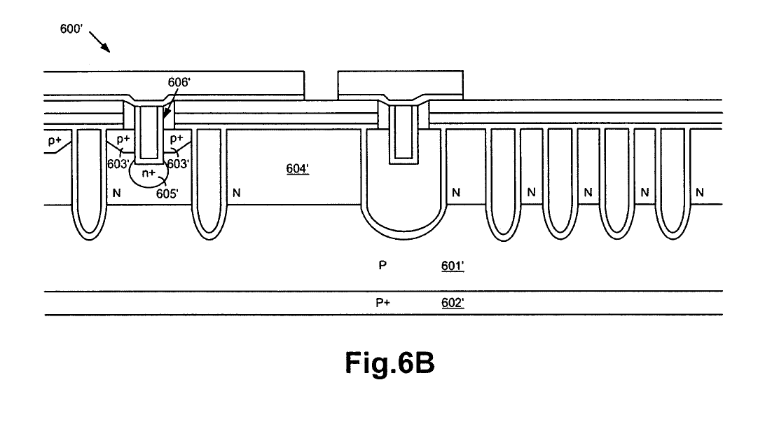

FIG. 6A shows another preferred embodiment of this invention wherein trench MOSFET 600 has a similar structure to the trench MOSFET 500 of FIG. 5A except the trench MOSFET 600 is P-channel trench MOSFET while the trench MOSFET 500 is N-channel MOSFET. The P-channel trench MOSFET 600 is formed in a P epitaxial layer 601 onto a P+ substrate 602, comprising p+ source regions 603 in an upper portion of N body regions 604 and n+ body contact area 605 around at least bottom of the trenched source-body contact 606.

FIG. 6B shows another preferred embodiment of this invention wherein trench MOSFET 600′ has a similar structure to the trench MOSFET 500′ of FIG. 5B except the trench MOSFET 600′ is P-channel trench MOSFET while the trench MOSFET 500′ is N-channel MOSFET. The P-channel trench MOSFET 600′ is formed in a P epitaxial layer 601′ onto a P+ substrate 602′, comprising p+ source regions 603′ in an upper portion of N body regions 604′ and n+ body contact area 605′ around at least bottom of the trenched source-body contact 606′.

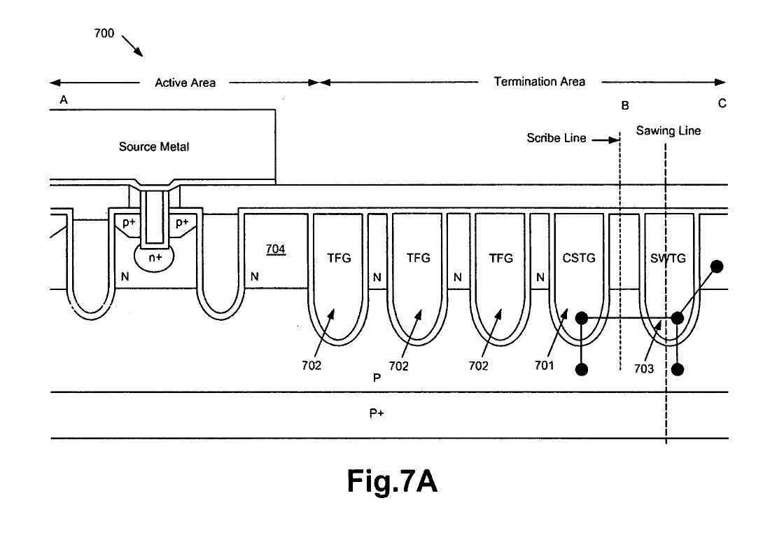

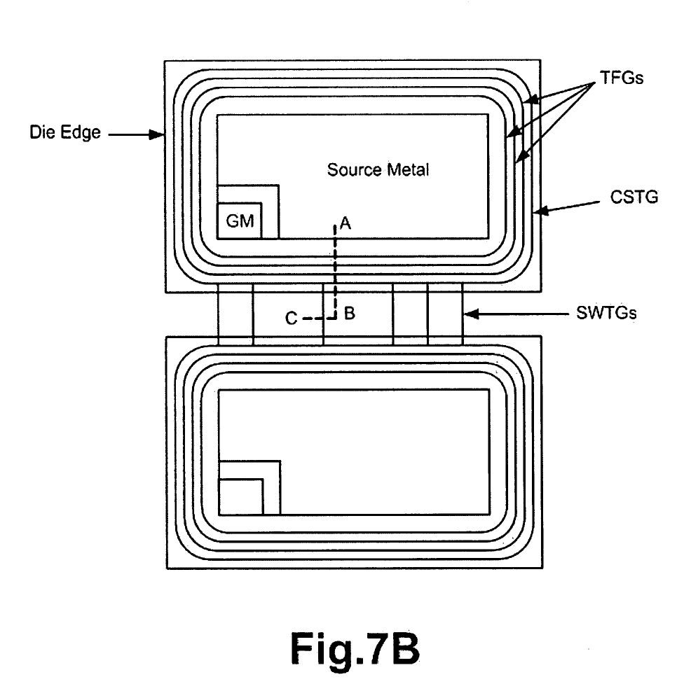

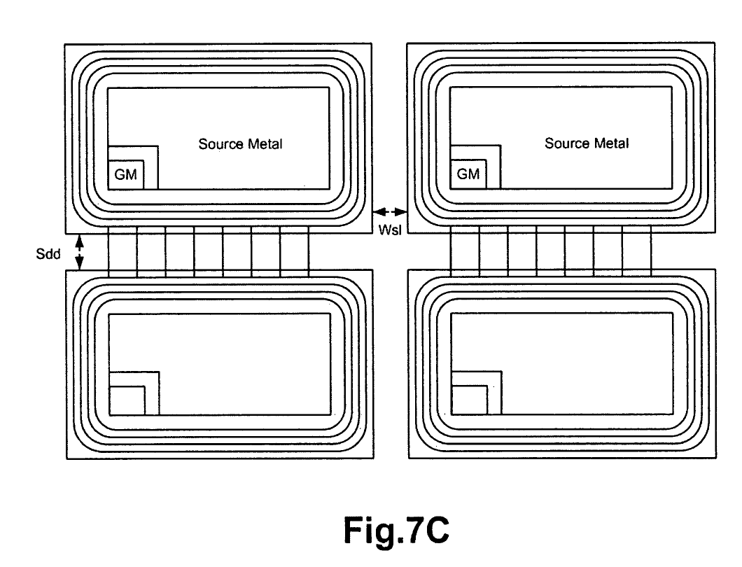

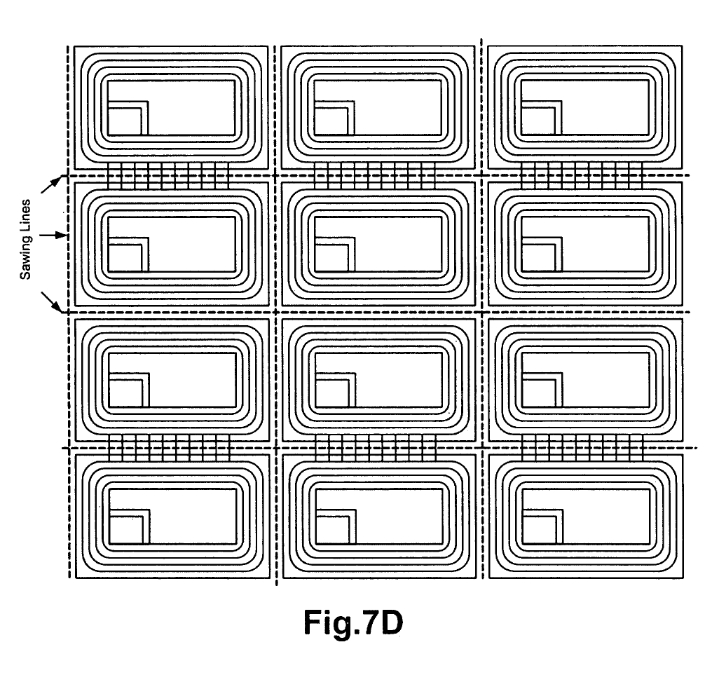

FIG. 7A is a cross-sectional view showing a preferred A-B-C cross section of FIG. 7B according to the present invention, wherein trench MOSFET 700 has a similar structure to the trench MOSFET 600 of FIG. 6A except the trench MOSFET 700 further comprises at least one trenched channel stop gate 701 (CSTG, as illustrated in FIG. 7A) formed in the termination area and around outside of the multiple trenched floating gates 702 (TFG, as illustrated in FIG. 7A), wherein each trenched channel stop gate 701 is connected to at least one sawing trenched gate 703 (SWTG, as illustrated in FIG. 7A), wherein each sawing trenched gate 703 is extended across a scribe line. The at least one trenched channel stop gate 701 and the at least one sawing trenched gate 703 are electrically shorted to the drain region and the N body regions 704 after die sawing through the sawing trenched gate 703.

FIG. 7B shows a dual dies consisted of two dies each comprising a trench MOSFET with trenched floating gates (TFGs, as illustrated in FIG. 7B) and at least one trenched channel stop gate (CSTG, as illustrated in FIG. 7B) according to the present invention, wherein the two dies are connected together with multiple sawing trenched gates (SWTGs, as illustrated in FIG. 7B) in such a way that die-to-die space (S_{dd}, as illustrated in FIG. 7C) between the two dies is as same as scribe line width (W_{SL}, as illustrated in FIG. 7C). FIG. 7D shows multiple dual dies layout of a preferred embodiment according to the present invention. The dual dies will be separated after sawing through the multiple sawing trenched gates along sawing lines indicated by dashed lines in FIG. 7D.

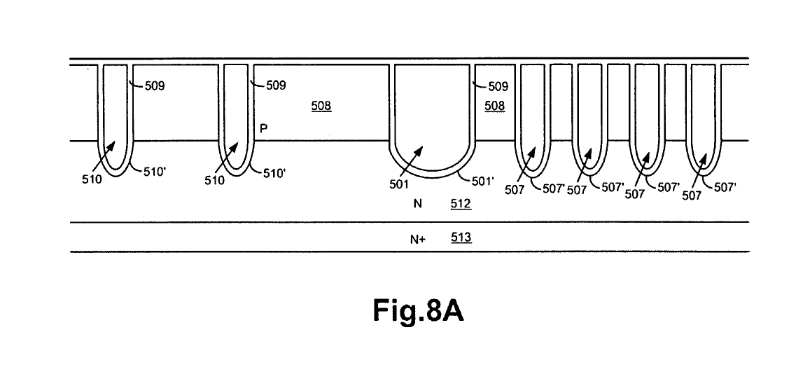

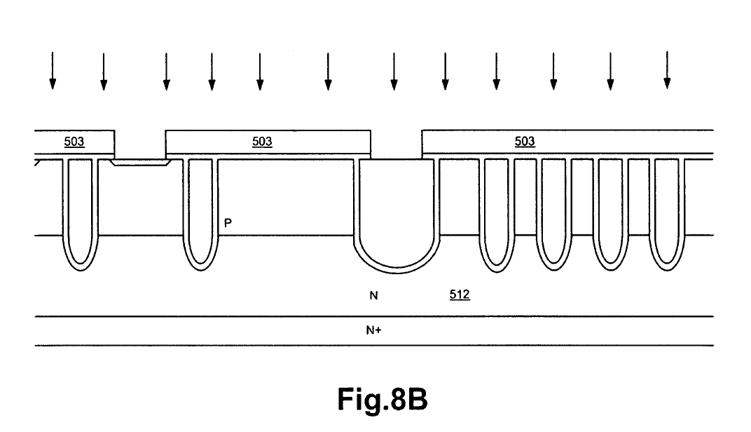

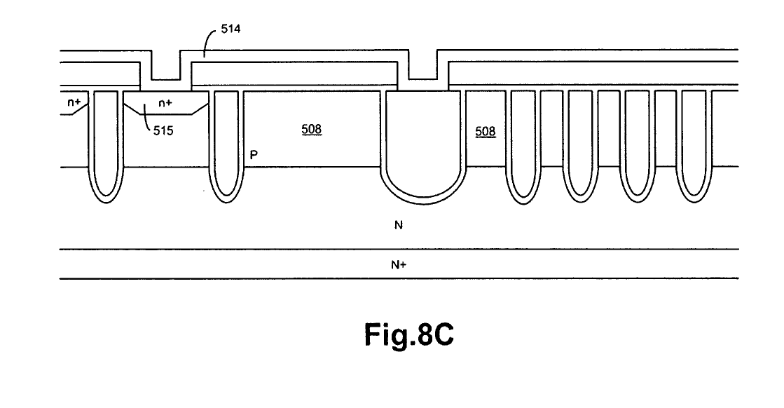

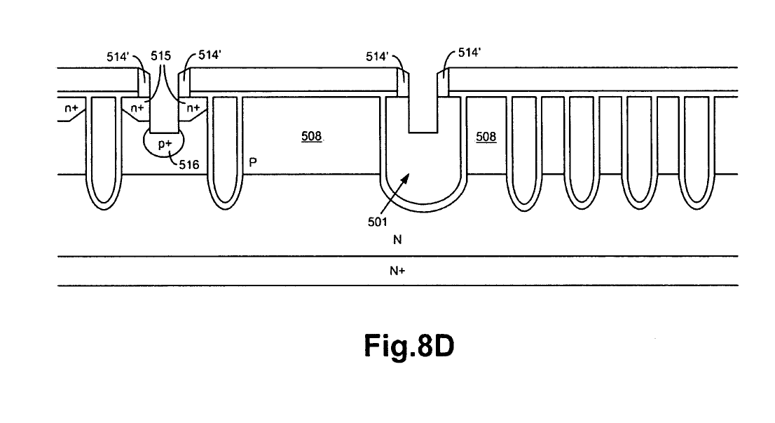

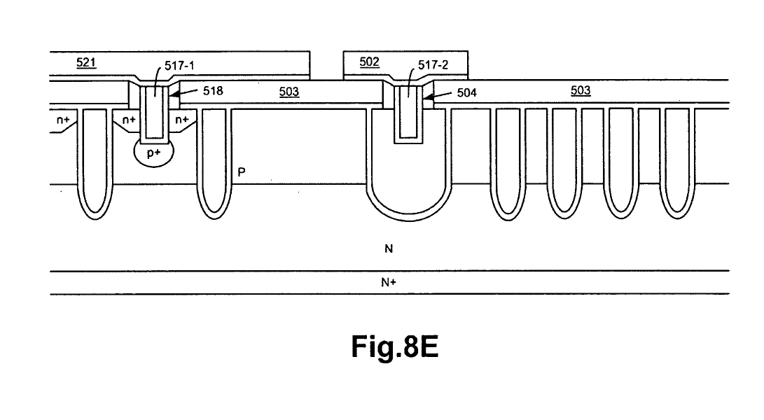

FIGS. 8A to 8E are cross-sectional views for showing manufacturing steps of the trench MOSFET 500 in FIG. 5A according to the present invention. Referring to FIG. 8A, an N epitaxial layer 512 is initially grown on a heavily doped N+ substrate 513 Next, a trench mask (not shown) is applied and followed by a trench etching process to define a plurality of gate trenches 510′, 501′ and 507′ in the N epitaxial layer 504. Then, a sacrificial oxide layer (not shown) is grown and etched to remove the plasma damaged silicon layer formed during the process of opening the gate trenches. Afterwards, a gate oxide layer 509 is deposited along inner surface of all the gate trenches and along a top surface of the N epitaxial layer 512. Then, a doped poly-silicon layer is filled into all gate trenches and followed by a poly-silicon chemical mechanical polishing (CMP) or an etching back process to leave the poly-silicon layer within the gate trenches to form a plurality trenched gates 510 in an active area, a trenched connection gate 501 and multiple trenched floating gates 507, respectively. Thereafter, after carrying out a P body dopant ion implantation step and a successive diffusion step, a plurality of P body regions 508 are formed in an upper portion of the N epitaxial layer 512 without using a body mask.

In FIG. 8B, a contact interlayer 503 is deposited on a top surface of the structure of FIG. 8A. Then, a contact mask (not shown) is employed and then followed by a dry oxide etching process to define a plurality of contact openings to expose a part top surface of the N epitaxial layer 512 for a followed n source dopant ion implantation step.

In FIG. 8C, a dielectric layer 514 composed of nitride, oxide or oxynitride is deposited on a top surface of the structure of FIG. 8B. Then, a source diffusion step is carried out after that there forms n+ source regions 515 near a top surface of the P body region 508 in an active area of the trench MOSFET without using a source mask.

In FIG. 8D, a dry silicon etch step is carried out to form dielectric sidewall spacers 514′ along the contact openings. Next, after carrying out a dry silicon etch process, contact openings are respectively etched into the P body region 502 after penetrating through the n+ source regions 515 and into the trenched connection gate 511. Then, after carrying out a contact dopant ion implantation and a step of rapid thermal annealing (RTA) process, a p+ body contact area 516 is formed underneath the n+ source regions 515 and surrounding at least bottom of the contact opening which is extending into the P body region 508.

In FIG. 8E, a barrier layer Ti/TiN or Co/TiN or Ta/TiN is deposited on sidewalls and bottoms of all the contact openings (as shown in FIG. 8E) followed by a step of RTA process for silicide formation. Then, a tungsten material layer is deposited onto the barrier layer, wherein the tungsten material layer and the barrier layer are then etched back to form contact metal plugs (517-1˜517-2) respectively for a trenched source-body contact 518 and a trenched gate contact 504. Then, a metal layer of Al alloys or Cu padded by a resistance-reduction layer Ti or Ti/TiN underneath is deposited onto the contact interlayer 503 and followed by a metal etching process by employing a metal mask (not shown) to form a gate metal layer 502 and a source metal layer 521.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET formed in an epitaxial layer of a first conductivity type and comprising a plurality of first trenched gates with each surrounded by a source region heavily doped with said first conductivity type in an active area encompassed in a body region of a second conductivity type above a drain region disposed on a bottom surface of a substrate of said first conductivity type, further comprising:
a plurality of contact openings formed into a contact interlayer over said epitaxial layer, with a dielectric sidewall spacer formed along each sidewall of said contact openings and adjacent to said contact interlayer;
a trenched source-body contact having upper sidewalls with each surrounded by said dielectric sidewall spacer, further penetrating through said source region and extending into said body region, connecting said source region and said body region to a source metal onto said contact interlayer; wherein
said source region has a lower doping concentration and a shallower source junction depth along a channel region than under said dielectric sidewall spacer at a same distance from a top surface of said epitaxial layer.

2. The trench MOSFET of claim 1, wherein said first conductivity type is N type and said second conductivity type is P type.

3. The trench MOSFET of claim 1, wherein said first conductivity type is P type and said second conductivity type is N type.

4. The trench MOSFET of claim 1, wherein said trench MOSFET further comprises a trenched connection gate adjacent to said active area, having a greater trench width than said trenched gates in said active area, wherein said trenched connection gate is connected to a gate metal layer through a trenched gate contact extending into a doped poly silicon layer filled in said trenched connection gate, wherein upper sidewalls of said trenched gate contact are also surrounded by said dielectric sidewall spacer.

5. The trench MOSFET of claim 1, wherein said trench MOSFET further comprises a termination area having multiple trenched floating gates surrounded by said body regions, wherein no said source region is formed in said termination area.

6. The trench MOSFET of claim 1, wherein said contact interlayer is composed of a single layer of NSG (non-doped silicate glass) such as SRO (silicon rich oxide).

7. The trench MOSFET of claim 1, wherein said contact interlayer is composed of a layer of NSG (non-doped silicate glass) and a layer of BPSG (boron-phosphorus-silicate glass).

8. The trench MOSFET of claim 1 further comprising at least one trenched channel stop gate formed in said termination area and around outside of said multiple trenched floating gates, each said trenched channel stop gate being connected to at least one sawing trenched gate, wherein each said sawing trenched gate is extended across a scribe line.

9. The trench MOSFET of claim 8, wherein said at least one trenched channel stop gate and said at least one sawing trenched gate are electrically shorted to a drain region and said body regions around said termination area.

10. The trench MOSFET of claim 1 further comprising a body contact area heavily doped with said second conductivity type dopant around at least bottom of said trenched source-body contact.

11. The trench MOSFET of claim 1, wherein said source metal is Al alloys or Cu alloys padded by a resistance-reduction layer such as Ti or Ti/TiN.

12. The trench MOSFET of claim 4, wherein and said gate metal layer is Al alloys or Cu alloys padded by a resistance-reduction layer such as Ti or Ti/TiN.

13. The trench MOSFET of claim 1, wherein said trenched source-body contacts is filled with W (tungsten) plugs padded by a barrier layer connecting with said source metal.

14. The trench MOSFET of claim 4, wherein and said trenched gate contact is filled with W (tungsten) plugs padded by a barrier layer connecting with said gate metal.

15. A semiconductor power device layout consisted of dual trench MOSFETs of claim 8, wherein each said sawing trenched gate being extended across over a space between said dual trench MOSFETs and connected with said trenched channel stop gate of said dual trench MOSFETs.

16. The semiconductor power device layout of claim 15, wherein said space between said dual trench MOSFETs has a width as same as scribe line.

17. The semiconductor power device layout of claim 15 wherein said trenched channel stop gate and said sawing trenched gate of each of said dual trench MOSFETs are shorted with a drain region of said dual trench MOSFETs after die sawing through said sawing trenched gate for separation of said dual trench MOSFETs.

18. The semiconductor power device layout of claim 15, wherein there is only one said trenched channel stop gate formed in each of said dual trench MOSFETs and connected to at least one said sawing trenched gate.

19. A method for forming the trench MOSFET of claim 1 comprising:
forming a plurality of trenched gates surrounded by body regions in an epitaxial layer;
forming a plurality of contact openings in a contact interlayer over said epitaxial layer to expose a part top surface of the epitaxial layer, wherein said contact opening is located between every two adjacent of said trenched gates;
implanting said epitaxial layer with source dopant through said contact openings;
depositing a dielectric layer along the top surface of said contact interlayer, and sidewalls and bottom of said contact openings;
diffusing said source dopant to form source regions surrounding said trenched gates;
carry out a dry oxide etch to form dielectric sidewall spacers along sidewalls of said contact openings; and
carrying out a dry silicon etch along said dielectric sidewall spacers to further etch said contact openings through said source region and extend into said body region.

20. The method of claim 19, wherein said body regions are formed without using a body mask.

21. The method of claim 19, wherein said forming dielectric sidewall spacers comprises depositing a dielectric layer and then carrying out a dry oxide etch.

22. The method of claim 21, wherein said carrying out said dry oxide etch is after diffusing said source dopant to form said source regions.
